(19) United States
(12) Patent Application Publication
(10) Pub. No.: US 2025/0298063 A1
(43) Pub. Date: Sep. 25, 2025

(54) METHOD FOR DETERMINING THE PRESENCE OF A FOREIGN METAL BODY AT THE INTERFACE BETWEEN AN NFC TRANSMITTER AND AN ELECTRICAL DEVICE TO BE CHARGED

(71) Applicant: Continental Automotive Technologies GmbH, Hannover (DE)

(72) Inventors: Guilherme Germano BUCHMEIER, Toulouse (FR); Dylan BEAUNEZ, Toulouse (FR)

(73) Assignee: Continental Automotive Technologies GmbH, Hannover (DE)

(21) Appl. No.: 19/068,639

(22) Filed: Mar. 3, 2025

(30) Foreign Application Priority Data
Mar. 25, 2024 (FR) FR2402935

(51) Int. Cl. G01R 19/25; H02J 50/12; H02J 50/60

(52) U.S. Cl. CPC G01R 19/25; H02J 50/12; H02J 50/60

(57) ABSTRACT

A method for determining the presence of a foreign metal body at the interface between an NFC transmitter, including at least one MOSFET, and an electrical device to be charged. The method includes: measuring the drain-source voltage of the MOSFET; deducing from this measurement a value representative of the presence of the body; and transmitting a signal and/or interrupting the charging cycle when the value reaches a predetermined threshold.

### CROSS REFERENCE TO RELATED APPLICATION

This application claims priority to French Patent Application No. FR2402935, filed Mar. 25, 2024, the contents of such application being incorporated by reference herein.

### FIELD OF THE INVENTION

The present invention relates to the field of the wireless charging of electrical devices.

### BACKGROUND OF THE INVENTION

Electrical devices requiring a low charging power, such as in-ear headphones, key fobs or connected watches, may be charged wirelessly by NFC (Near-Field Communication) transmitters.

The charging cycle is carried out by placing the electrical device in proximity to the transmitter so as to be able to inductively induce a charging current inside the electrical device.

Up until recently, this NFC technology made it possible to recharge only very low-power electrical devices, that is to say of less than 1 W.

By using a MOSFET (Metal-Oxide-Semiconductor Field-Effect Transistor) in the circuits of NFC transmitters, it is possible to charge electrical devices the power of which typically reaches of the order of 3W, thus broadening the field of application of the NFC technology for recharging electrical devices.

One drawback related to using NFC technology for recharging electrical devices is the possible intrusion of a foreign metal body in the interface separating the NFC transmitter from the device to be recharged.

Such a foreign body may for example be a coin, a piece of metallic paper, etc.

Under the effect of the NFC radiation, this foreign body may heat up, this possibly risking burning the user, or even risking a fire.

In addition, this foreign body disrupts the transmission of power to the electrical device to be recharged, thus degrading the expected quality of service.

Various solutions have been able to be explored in order to detect the presence of a foreign metal body, in particular power balance methods and current and voltage measurement methods, it being possible for these methods to be used alone or in combination.

In use, these methods proved to be not very reliable-in particular at frequencies above 1 MHz where the measurement of electrical parameters is not accurate enough and/or the power balance is not sufficient on its own.

It was then envisaged to use measurements of non-electrical parameters such as pressure and temperature, requiring the use of expensive sensors the reliability of which did not always meet expectations.

### SUMMARY OF THE INVENTION

An aspect of the present invention is thus in particular to provide a method for determining the presence of a foreign metal body at the interface between an NFC transmitter, comprising at least one MOSFET, and an electrical device to be charged, which makes it possible to overcome these drawbacks of the prior art.

This aspect of the invention is achieved with a method for determining the presence of a foreign metal body at the interface between an NFC transmitter, comprising at least one MOSFET, and an electrical device to be charged, comprising the steps consisting in:
measuring the drain-source voltage of the MOSFET,
deducing from this measurement a value representative of the presence of said body,
transmitting a signal and/or interrupting the charging cycle when said value reaches a predetermined threshold.

Specifically, various research studies and experiments made it possible to demonstrate that the drain-source voltage (that is to say between the drain and the source) of the MOSFET contained information strongly correlated with the presence of a metal body in the interface between the NFC transmitter and the electrical device to be charged.

Thus, by measuring the drain-source voltage and by applying appropriate digital processing operations thereto, it is possible to extract therefrom information which makes it possible to distinguish situations in which the charging power is at least partly transmitted to a foreign metal body instead of being transmitted entirely to the electrical device to be charged.

Such a method, which requires no modification to the hardware of an NFC transmitter but simply algorithmic modifications, makes it possible to considerably increase the reliability of detection of a foreign metal body in the interface between the NFC transmitter and the electrical device to be charged, this being done at a lower cost.

According to other optional features of the method according to an aspect of the invention:
the value representative of the presence of the foreign metal body is determined from the harmonics of said drain-source voltage;
said drain-source voltage is analyzed by Fourier transform;
the product of the fundamental frequency of the drain-source voltage and the input current of the NFC transmitter is furthermore used to determine said representative value.

An aspect of the present invention also relates to an NFC transmitter comprising at least one MOSFET, memory means in which said threshold value has been pre-recorded, means for measuring the drain-source voltage, and means for calculating said representative value and for comparing with said threshold value.

### BRIEF DESCRIPTION OF THE DRAWINGS

Other features and advantages of aspects of the invention will become apparent on reading the following description, with reference to the appended figures which illustrate:

FIG. 1: schematically, an NFC transmitter according to an aspect of the invention positioned facing an electrical device to be charged;

FIG. 2: a series of curves of the drain-source voltage of a MOSFET forming part of an NFC transmitter according to an aspect of the invention, for various positions with respect to the electrical device to be charged, and with or without a foreign metal body; and

FIG. 3: a series of graphs of drain-source voltage/frequency corresponding to the curves of FIG. 2, respectively, after application of a Fourier transform.

### DETAILED DESCRIPTION OF EXEMPLARY EMBODIMENTS

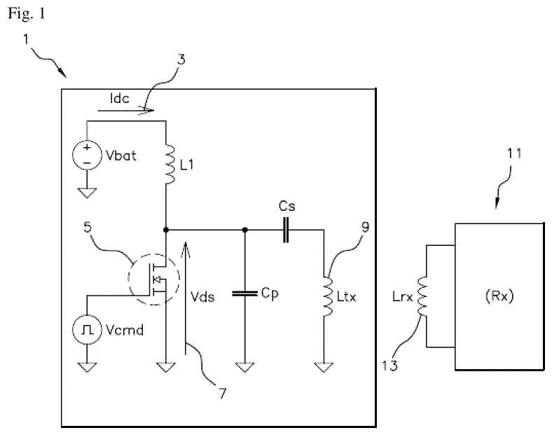

As can be seen in FIG. 1, the NFC transmitter 1 according to an aspect of the invention typically comprises a DC current input 3, supplying power in particular to at least one MOSFET 5 having a drain-source voltage V_{ds} 7 itself supplying power to at least one coil 9 which is capable of inductively charging an electrical device 11 forming a receiver which is positioned facing the NFC transmitter 1 and is itself provided with its own induction coil 13.

Typically, this type of transmitter having a MOSFET makes it possible to obtain a class E amplifier able to charge electrical devices the power of which may be of the order of 3 W: these small rechargeable electrical devices comprise for example in-ear headphones, electronic key fobs, connected watches, etc.

The NFC transmitter 1 also comprises memory means, and a microcomputer making it possible in particular, on the basis of the measurement of the drain-source voltage V_{ds} 7 of the MOSFET 5 and of the supply current 3 of the transmitter, to perform the operations that will be described below.

According to an aspect of the invention, a value extracted from the measurement of the drain-source voltage V_{ds} 7 is calculated in real time, for which value it will have been possible to ensure through prior experiments that it is representative of the presence of a foreign metal body in the interface between the NFC transmitter 1 and the electrical device to be charged 11.

In this instance, it has emerged that a highly representative value could be expressed in the form:

$$OEi = aH 12 + bH 22 + + xHi 2 \qquad ( 1 )$$

where OEi is the value indicative of the presence of a foreign metal body, H1, etc. Hi are the harmonic frequencies of the drain-source voltage V_{ds} 7, and the coefficients a, b, . . . x result from a prior calibration of the NFC transmitter 1.

This calibration, carried out using various types of foreign metal bodies (for example a coin, a piece of metallic paper, etc.), is performed once and for all for a given NFC transmitter, and the coefficients a, b, . . . , x are stored in the memory of the NFC transmitter 1.

The harmonic frequencies H₁, . . . , Hᵢ are calculated in real time by the microcomputer of the NFC transmitter 1, by Fourier transform.

Preferably, and in order to increase precision, a term PFOM representative of the power consumed by the MOSFET 5 is added to the above-referenced formula, which term is obtained by multiplying the intensity of the current 3 supplying power to the NFC transmitter by the fundamental frequency of the drain-source voltage V_{ds}:

$$OEi = aH 12 + bH 22 + + xHi 2 + PFOM \qquad ( 2 )$$

This value OEᵢ, calculated in real time by the microcomputer of the NFC transmitter 1, is compared, at each calculation cycle, with a threshold value OE_{threshold}, for which value it will have been possible to determine beforehand and once and for all, during calibration operations, that it is indicative of the presence of a foreign metal body in the interface between the NFC transmitter 1 and the electrical device to be charged 11.

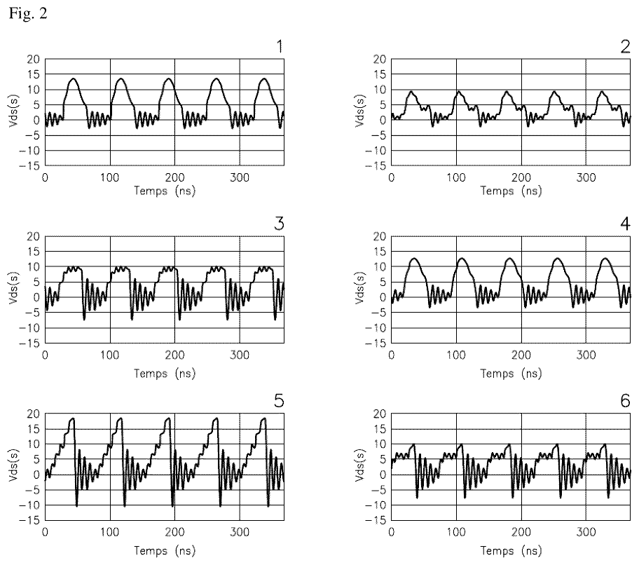

By way of example, curves 1 to 6 of FIG. 2 illustrate the drain-source voltage Vds of the MOSFET 5 over time, for various respective positions of an electrical device to be charged (“receiver”) and of a foreign metal body with respect to the NFC transmitter 1:
curve 1: electrical device 11 centered with respect to the transmitter 1, without a foreign metal body,
curve 2: electrical device 11 to the side of the transmitter 1, without a foreign metal body,
curve 3: electrical device 11 centered with respect to the transmitter 1, with a foreign metal body centered with respect to the transmitter,
curve 4: electrical device 11 centered with respect to the transmitter 1, with a foreign metal body to the side of the transmitter,
curve 5: electrical device 11 to the side of the transmitter 1, with a foreign metal body centered with respect to the transmitter,
curve 6: electrical device 11 to the side of the transmitter 1, with a metal body to the side of the transmitter.

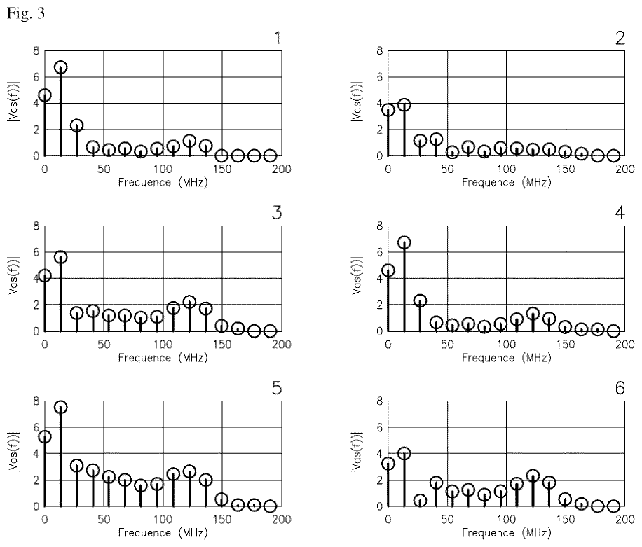

In these examples, the situations considered to be critical, that is to say to be undesirable since they are liable to lead to a situation where the foreign metal body heats up and/or the electrical device 11 is incorrectly charged, are those in FIGS. 3, 5 and 6.

Graphs 1 to 6 of FIG. 3 illustrate the Fourier transforms of curves 1 to 6 of FIG. 2, respectively.

As can be seen in this FIG. 3, graphs 3, 5 and 6 are those which comprise harmonics having the highest amplitudes, this making it possible to understand why formulae (1) and (2), using the harmonics of the above-mentioned drain-source voltage Vas, may reflect the situations considered to be critical in terms of a foreign metal body heating up and/or of incorrect charging.

When the value OEᵢ reaches the value OE_{threshold}, this indicates, with a high confidence interval, that a foreign metal body is located in the interface between the NFC transmitter 1 and the electrical device to be charged 11, and the transmitter 1 is then programmed to transmit a signal for the attention of the user or else to stop the charging cycle, in order to prevent the foreign metal body from heating up and/or the electrical device 11 from incorrectly charging.

By way of illustration, in one particular case, it will be possible to use the following calculation formula for the value OEᵢ:

$$OEi = 4.8 H 32 + H 52 + 1.8 ( H 4 / H 3 ) 2 + 3 PFOM$$

and with a threshold value OEthreshold of between 1.86 and 2.04, this formula has made it possible to detect critical situations (heating up of a foreign metal body and/or incorrect charging of the electrical device 11) with 93.6% success.

As can be understood in the light of the above description, the method according to an aspect of the invention makes it possible, solely by implementing a suitable algorithm and with no particular modification to the hardware of an NFC transmitter having a MOSFET, to detect the presence of a foreign metal body in the interface between the transmitter and the electrical device to be charged.

This algorithm proves to be very reliable in practice, in particular in frequency ranges higher than 1 MHZ, in which the detection methods of the prior art fail.

In an aspect of the present invention, the MOSFET therefore combines two functions: in addition to its basic function allowing electrical devices of relatively low power to be inductively recharged, and by virtue of an algorithm developed especially for this purpose, the MOSFET may fulfill the function of a sensor for sensing the presence of a metal object interposed between the NFC transmitter and an electrical device to be recharged.

Naturally, the invention is described in the preceding text by way of example. It is understood that a person skilled in the art is able to produce various variant embodiments of the invention without thereby departing from the scope of the invention.

1. A method for determining the presence of a foreign metal body at the interface between an NFC transmitter, comprising at least one MOSFET, and an electrical device to be charged, the method comprising:
measuring the drain-source voltage of the MOSFET,
deducing from this measurement a value representative of the presence of said body,
transmitting a signal and/or interrupting the charging cycle when said value reaches a predetermined threshold,
wherein the product of the fundamental frequency of the drain-source voltage and the input current of the NFC transmitter is furthermore used to determine said representative value.

2. The method as claimed in claim 1, wherein the value representative of the presence of the foreign metal body is determined from the harmonics of said drain-source voltage.

3. The method as claimed in claim 1, wherein said drain-source voltage is analyzed by Fourier transform.

4. An NFC transmitter comprising at least one MOSFET, a memory in which a threshold value has been pre-recorded, means for measuring the drain-source voltage, and means for calculating a representative value and for comparing with said threshold value, said transmitter being programmed to transmit a signal or to stop the charging cycle when said value reaches a predetermined threshold.
